(19) United States
(12) Patent Application Publication
(10) Pub. No.: US 2014/0116974 A1
(43) Pub. Date: May 1, 2014

(54) FRAME WITH CONNECTING MEMBER FOR CONNECTING BARS OF THE FRAME

(71) Applicant: WEI WANG, Shenzhen (CN)

(72) Inventor: WEI WANG, Shenzhen (CN)

(21) Appl. No.: 13/685,517

(22) Filed: Nov. 26, 2012

(30) Foreign Application Priority Data
Nov. 1, 2012 (CN) 201210430282X

(51) Int. Cl. H01L 31/048

(52) U.S. Cl. CPC H01L 31/048
USPC 211/182

(57) ABSTRACT

A modular frame includes a number of bars connected end by end, and a number of connecting members connecting every two adjacent bars. Each bar includes an outer sidewall and an inner sidewall parallel to the outer sidewall. A first plate and a second plate are connected between the outer sidewall and the inner sidewall. The first plate, the second plate, the outer sidewall, and the inner sidewall bound a receiving space. Each connecting member includes two connecting plates received in adjacent receiving spaces. Each connecting plate defines a groove to engage with a locking block extending from an interior sidewall of each bar.

### BACKGROUND

1. Technical Field

The present disclosure relates to frames and, particularly, to a frame including a connecting member for connecting two adjacent bars of the frame.

2. Description of Related Art

A modular frame, to hold, for example, a photovoltaic panel or sheet, includes four bars connected end to end. Every two adjacent bars are connected to each other through an L-shaped connecting member. The connecting member is connected to the bars through screwing or riveting, which is inconvenient and renders any re-use more difficult.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of an assembled frame.

FIG. 2 is an exploded, isometric view of a part of the frame of FIG. 1, wherein the frame includes a connecting member.

FIG. 3 is an enlarged view of the connecting member of FIG. 2, viewed from another aspect.

FIG. 4 is a cross-sectional view taken along the line IV-IV of FIG. 1.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean “at least one.”

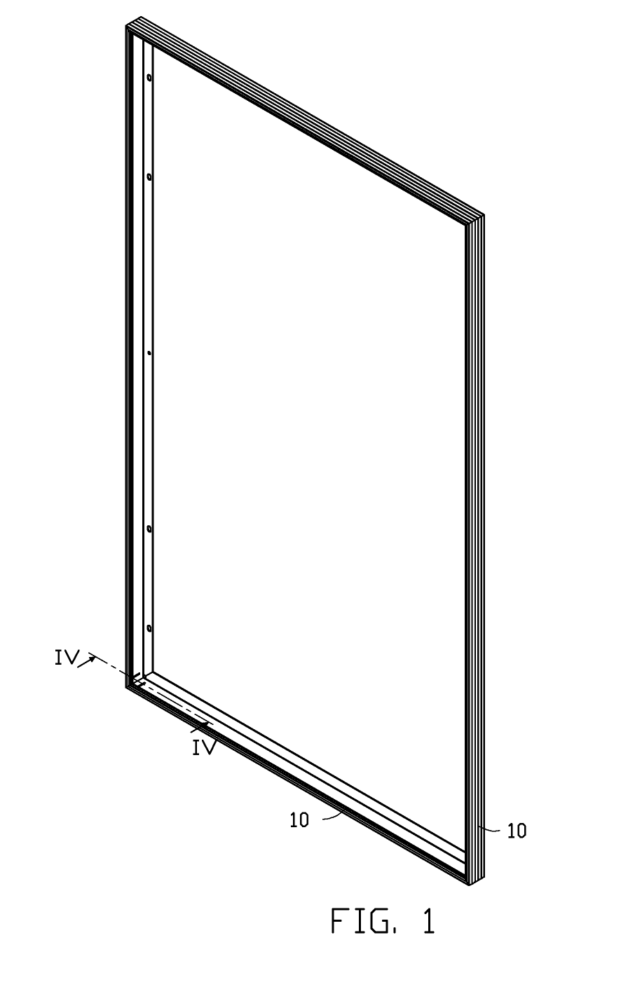

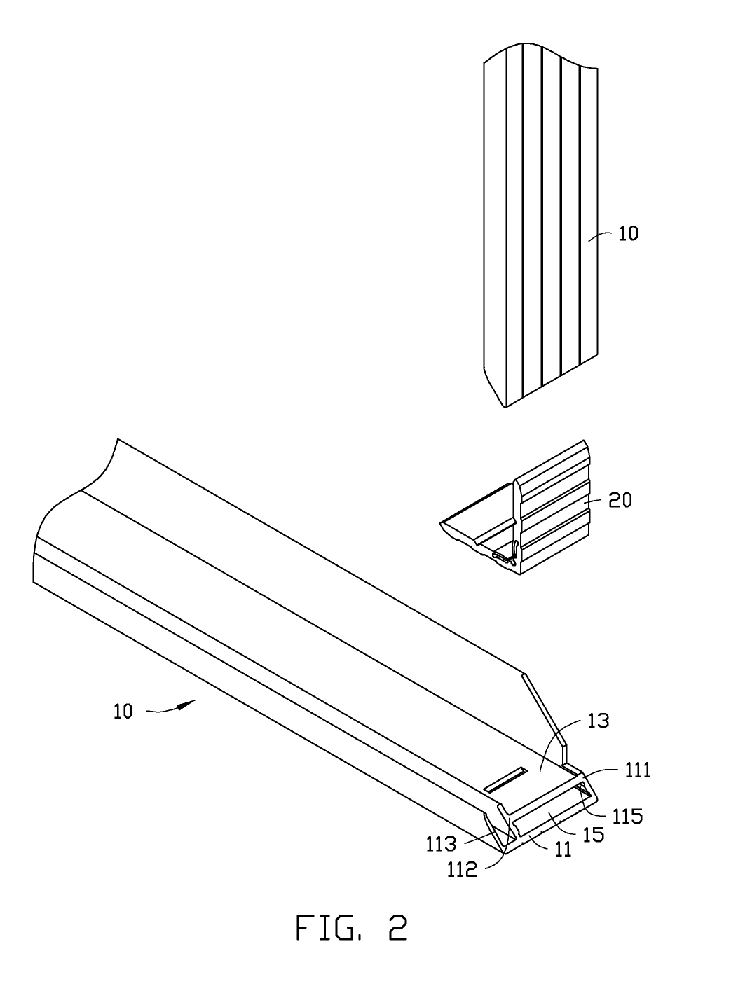

Referring to FIG. 1 and FIG. 2, an embodiment of a frame for mounting a photovoltaic panel or sheet (not shown) is illustrated. The frame includes four bars 10, and a connecting member 20 between every two adjacent bars 10. In the embodiment, the bars 10 are made of aluminum.

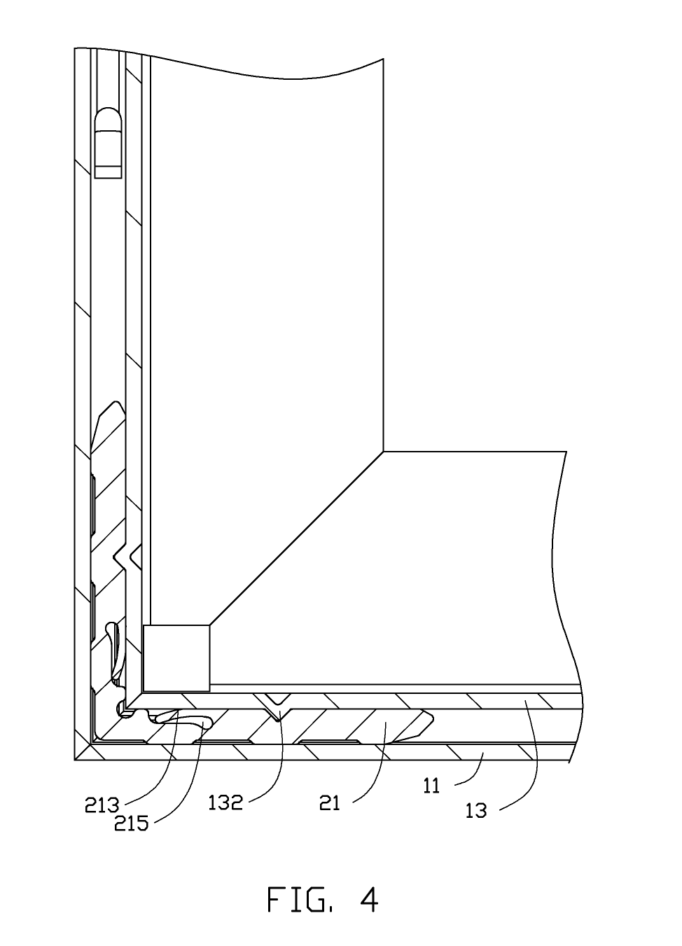

Each bar 10 includes an outer plate 11, an inner plate 13 parallel to the outer plate 11, a first sidewall 111 connected between first sides of the outer plate 11 and the inner plate 13, a second sidewall 112 connected between second sides of the outer plate 11 and the inner plate 13, and a third sidewall 113 extending from an edge of the outer plate 11 adjacent to the second side of the outer plate 11 and parallel to the second sidewall 112. The outer plate 11, the inner plate 13, the first sidewall 111, and the second sidewall 112 together bound a receiving space 15. The second sidewall 112, the third sidewall 113, and the outer plate 11 together bound a channel for receiving a side of the photovoltaic panel. A raised portion 115 extends into the receiving space 15 from an inner surface of each of the first sidewall 111 and the second sidewall 112, the length of the raised portion 155 being at least equal to the length of one connecting plate of a connecting member 20, as hereinafter described. A step or block (block 132) extends into the receiving space 15 from an inner surface of the inner plate 13, as shown in FIG. 4.

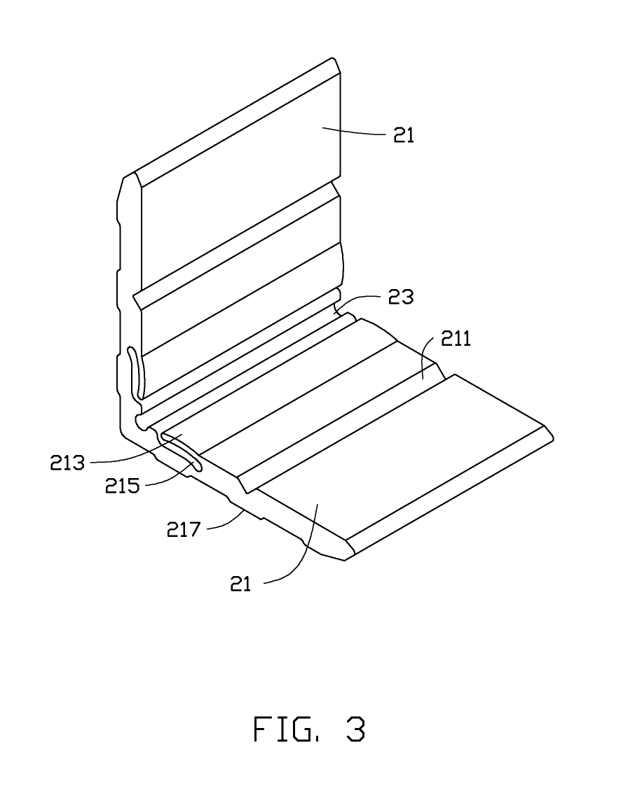

Referring to FIG. 3, each connecting member 20 is substantially L shaped, and includes two connecting plates 21 perpendicular to each other. A channel 23 is defined in the junction of the connecting plates 21. Each connecting plate 21 defines a substantially V-shaped groove 211, parallel to the channel 23, to correspond to a block 132. An arced resilient portion 213 extends from an inner surface of each of the connecting plates 21 towards the channel 23. A space 215 exists between each resilient portion 213 and the inner surface of the connecting plate 21 from which each resilient portion 213 extends. A plurality of anti-slip strips 217 are formed on an outer surface of each connecting plate 21. In the embodiment, the connecting member 20 is made of aluminum.

Referring to FIG. 4, in assembly, each of the connecting plates 21 is pressed into a receiving space 15 of each bar 10, until all the end edges of the inner plates 13 perpendicularly abut one another. The raised portions 115 exert slight pressure on the two opposite edges of the connecting plate 21. The block 132 is engaged in the groove 211 of the connecting plate 21. The resilient portion 213 is deformed into the space 215 to elastically abut the inner plate 13. The anti-slip strips 217 abut the outer plate 11. Thus, the connecting member 20 connects two adjacent bars 10 precisely and strongly.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

1. A frame, comprising:
four bars, each comprising an outer plate, an inner plate parallel to the outer plate, a first sidewall connected between first sides of the outer and inner plates, and a second sidewall connected between second sides of the outer and inner plates, wherein the first sidewall, the second sidewall, the outer plate, and the inner plate together bound a receiving space; and
four connecting members, each comprising two connecting plates respectively engaged in the receiving spaces of two adjacent ones of the four bars, wherein the connecting plates of each connecting member are perpendicular to each other and integrally formed into one solid unit;
wherein each of the connecting plates defines a groove, a block is formed adjacent to each of two opposite ends of and from an inner surface of the inner plate of each bar and engaged in the groove of a corresponding one of the two connecting plates of the corresponding one of the four connecting members;
wherein a resilient portion extends from an inner surface of each of the connecting plates toward the inner surface of the corresponding inner plate, a space is defined between the resilient portion and the inner surface of the corresponding connecting plate, the resilient portion is deformed toward the space to elastically abut the inner plate.

2. (canceled)

3. The frame of claim 1, wherein the resilient portion is elongated and arced.

4. The frame of claim 1, wherein a plurality of anti-slip strips is formed on an outer surface of each connecting plate, to abut the outer plate.

5. The frame of claim 1, wherein an inner surface of each of the first sidewall and the second sidewall comprises a raised portion, the raised portions of the first and second sidewalls abut two opposite edges of the corresponding connecting plate.

6. The frame of claim 1, wherein, a channel is defined in a junction of the connecting plates of each connecting member.

7. The frame of claim 6, wherein the groove is parallel to the channel of the connecting member.
